(19) United States
(12) Patent Application Publication
(10) Pub. No.: US 2023/0197903 A1
(43) Pub. Date: Jun. 22, 2023

(54) DISPLAY DEVICE

(71) Applicant: LG Display Co., Ltd., Seoul (KR)

(72) Inventors: Hyeonhye YU, Siheung-si (KR); SeHong PARK, Paju-si (KR)

(21) Appl. No.: 18/060,869

(22) Filed: Dec. 1, 2022

(30) Foreign Application Priority Data
Dec. 22, 2021 (KR) 10-2021-0184972

(51) Int. Cl. H01L 33/38; H01L 27/15; H01L 33/62

(52) U.S. Cl. CPC H01L 33/382; H01L 27/156; H01L 33/62

(57) ABSTRACT

According to an aspect of the present disclosure, a display device includes a substrate including a plurality of sub pixels; a first electrode on the substrate and corresponding to each of the plurality of sub pixels; a bank on the first electrode and including an opening which exposes the first electrode; a partition on the first electrode in the opening; a light emitting layer on the first electrode and the partition; and a second electrode on the light emitting layer, in which the light emitting layer is disposed to have a structure disconnected by the partition in the opening.

### CROSS-REFERENCE TO RELATED APPLICATIONS

This application claims the priority of Korean Patent Application No. 10-2021-0184972 filed on Dec. 22, 2021, in the Korean Intellectual Property Office, the disclosure of which is incorporated herein by reference.

### BACKGROUND

### Technical Field

The present disclosure relates to a display device, and more particularly, to a display device which is capable of improving a light extraction efficiency.

### Description of the Related Art

Currently, as it enters a full-scale information era, a field of a display device which visually expresses electrical information signals has been rapidly developing and studies are continued to improve performances of various display devices such as a thin thickness, a light weight, and low power consumption.

Among various display devices, a light emitting display device is a self-emitting display device so that a separate light source is not necessary, which is different from the liquid crystal display device. Therefore, the light emitting display device may be manufactured to have light weight and small thickness. Further, the light emitting display device is driven at a low voltage so that it is advantageous not only in terms of power consumption, but also in terms of color implementation, a response speed, a viewing angle, and a contrast ratio (CR). Therefore, it is expected to be utilized in various fields.

### BRIEF SUMMARY

A technical benefit to be achieved by the present disclosure is to provide a display device which improves a waveguide mode loss.

Another technical benefit to be achieved by the present disclosure is to provide a display device which increases a light extraction efficiency.

Technical benefits of the present disclosure are not limited to the above-mentioned technical benefits, and other technical benefits, which are not mentioned above, can be clearly understood by those skilled in the art from the following descriptions.

According to an aspect of the present disclosure, a display device includes a substrate including a plurality of sub pixels; a first electrode on the substrate and corresponding to each of the plurality of sub pixels; a bank on the first electrode and including an opening which exposes the first electrode; a partition on the first electrode in the opening; a light emitting layer on the first electrode and the partition; and a second electrode on the light emitting layer, in which the light emitting layer is disposed to have a structure disconnected by the partition in the opening. Other detailed matters of the embodiments are included in the detailed description and the drawings.

According to the present disclosure, an emission area of a sub pixel is divided into a plurality of parts to improve a loss caused by a waveguide mode.

According to the present disclosure, a light extraction efficiency of a plurality of sub pixels is increased to improve a luminance and a lifespan of the display device.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an embodiment of the present disclosure;

FIG. 2 is an enlarged plan view of a sub pixel of FIG. 1;

FIG. 3 is a cross-sectional view taken along a line III-III′ of FIG. 2;

FIG. 4A is a cross-sectional view taken along a line IVa-IVa′ of FIG. 2;

FIG. 4B is a cross-sectional view taken along a line IVb-IVb′ of FIG. 2;

FIG. 4C is a cross-sectional view taken along a line IVc-IVc′ of FIG. 2;

FIG. 4D is a cross-sectional view taken along a line IVd-IVd′ of FIG. 2;

FIG. 5 is a graph illustrating a change in a light efficiency according to a number of emission areas; and

FIGS. 6 and 7 are plan views of a display device according to various embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

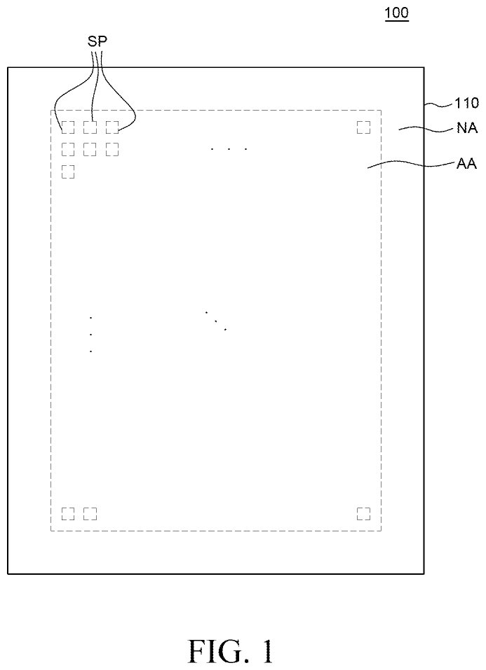

FIG. 1 is a plan view of a display device according to an embodiment of the present disclosure. In FIG. 1, for the convenience of description, among various configurations of the display device 100, a substrate 110 is illustrated. Referring to FIG. 1, the substrate 110 includes an active area AA and a non-active area NA.

The active area AA is disposed at a center portion of the substrate 110 and images may be displayed in the active area of the display device 100. In the active area AA, a display element and various driving elements for driving the display element may be disposed. For example, the display element may be configured by a light emitting diode 140 including a first electrode 141, a light emitting layer 142, and a second electrode 143 to be described below. Further, various driving elements for driving the display element, such as a transistor 120, a capacitor, or wiring lines may be disposed in the active area AA.

A plurality of sub pixels SP may be included in the active area AA. The sub pixel SP is a minimum unit which configures a screen and each of a plurality of sub pixels SP may include a light emitting diode 140 and a driving circuit. A plurality of sub pixels SP may be positioned at regions of overlap of a plurality of gate lines disposed in a first direction and a plurality of data lines disposed in a second direction which is different from the first direction, but is not limited thereto. Here, the first direction may be a horizontal direction of FIG. 1 and the second direction may be a vertical direction of FIG. 1, but are not limited thereto.

The driving circuit of the sub pixel SP is a circuit for controlling the driving of the light emitting diode 140. For example, the driving circuit may include a switching transistor, a driving transistor, and a capacitor. The driving circuit may be electrically connected to signal lines such as a gate line and a data line which are connected to a gate driver and a data driver disposed in the non-active area NA.

The non-active area NA is disposed in a circumferential area of the substrate 110 and in the non-active area, images may not be displayed. The non-active area NA is disposed so as to enclose the active area AA, but is not limited thereto. Various components for driving a plurality of sub pixels SP disposed in the active area AA may be disposed in the non-active area NA. For example, a driving IC, a driving circuit, a signal line, and a flexible film which supply a signal for driving a plurality of sub pixels SP may be disposed. In this case, the driving IC may include a gate driver and a data driver.

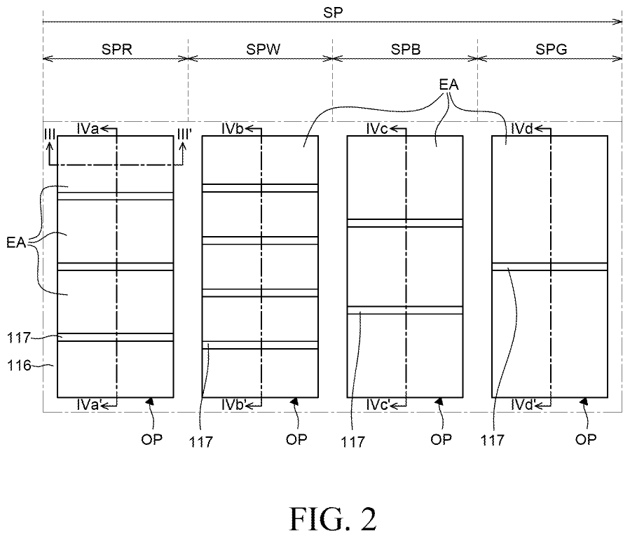

FIG. 2 is an enlarged plan view of a sub pixel of FIG. 1. In FIG. 2, for the convenience of description, among various configurations of the display device 100, a bank 116 and a partition 117 are illustrated.

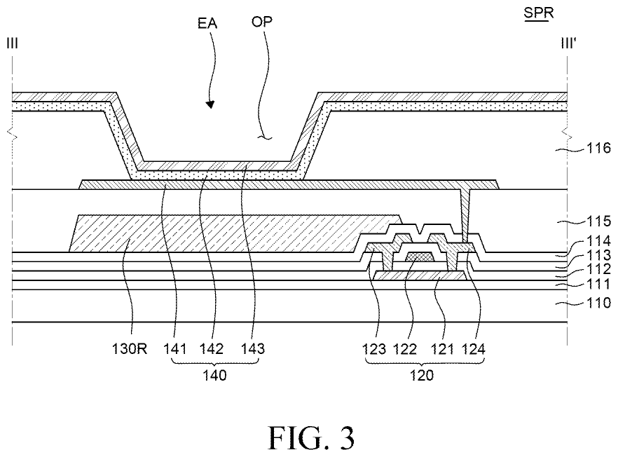

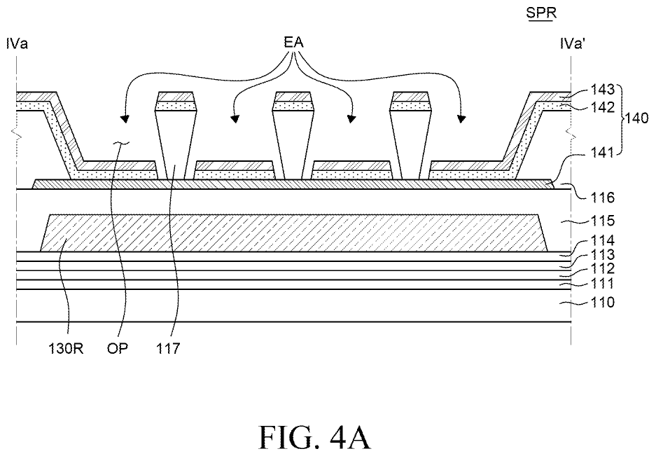

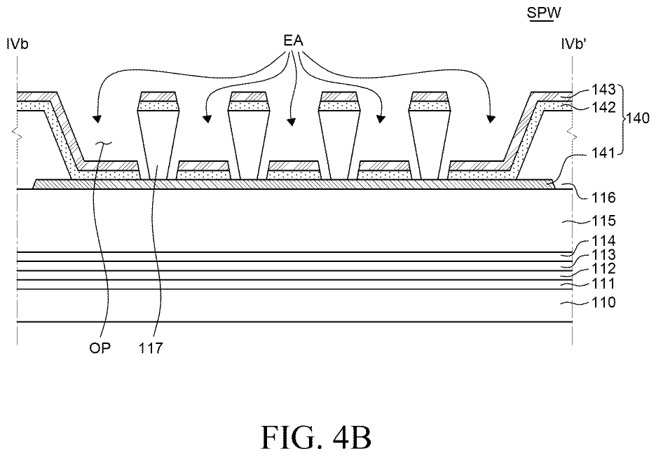

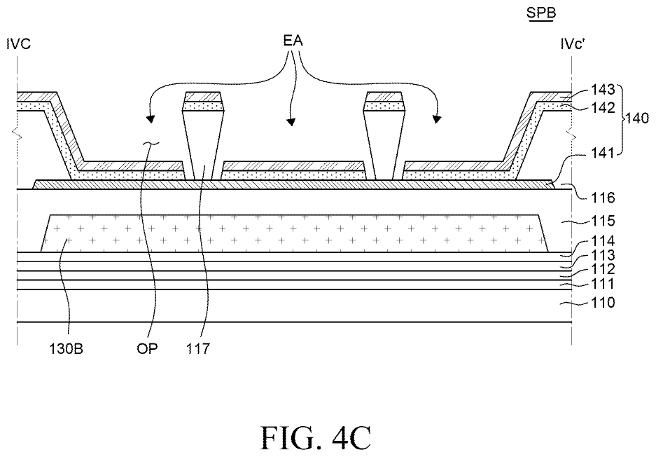

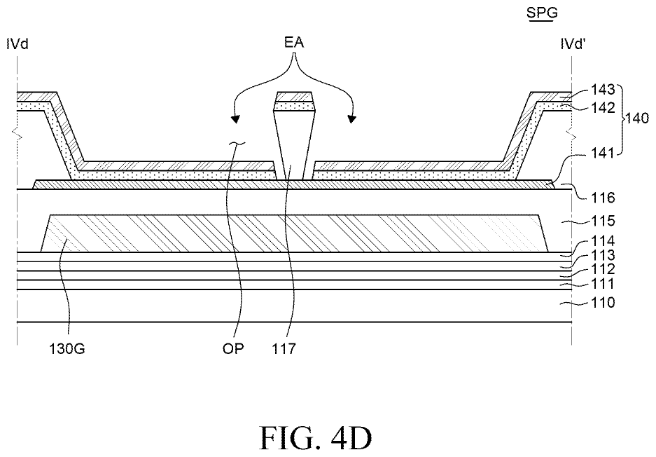

Referring to FIG. 2, a plurality of sub pixels SP includes a red sub pixel SPR, a white sub pixel SPW, a blue sub pixel SPB, and a green sub pixel SPG. Each of the red sub pixel SPR, the white sub pixel SPW, the blue sub pixel SPB, and the green sub pixel SPG may include an exposed area by an opening OP of the bank 116. At this time, the opening OP may be divided into a plurality of regions by the partition 117. Even though in FIG. 2, it is illustrated that the partition 117 extends in the first direction, the shape of the partition 117 is not limited thereto. The regions divided by the partition 117 may correspond to the emission area EA. The emission area EA may refer to a region in which the first electrode 141 of the light emitting diode 140 is in direct contact with the light emitting layer 142 so that light is substantially emitted. Further, the emission area EA may refer to an area enclosed by the bank 116 and the partition 117. This will be described in more detail with reference to FIGS. 3 to 4D.

FIG. 3 is a cross-sectional view taken along the line III-III′ of FIG. 2.

Referring to FIG. 3, the display device 100 includes a substrate 110, a transistor 120, a color filter 130R, and a light emitting diode 140.

In the meantime, the display device 100 may be configured by a top emission type or a bottom emission type, depending on an emission direction of light which is emitted from the light emitting diode.

According to the top emission type, light emitted from the light emitting diode is emitted above the substrate on which the light emitting diode is disposed. In the case of the top emission type, a reflective layer may be formed below the anode to allow the light emitted from the light emitting diode to travel above the substrate, that is, toward the cathode.

According to the bottom emission type, light emitted from the light emitting diode is emitted to below the substrate on which the light emitting diode is disposed. In the case of the bottom emission type, the anode may be formed only of a transparent conductive material and the cathode may be formed of the metal material having a high reflectance to allow the light emitted from the light emitting diode to travel below the substrate.

Hereinafter, for the convenience of description, the description will be made by assuming that the display device 100 according to an embodiment of the present disclosure is a bottom emission type display device, but it is not limited thereto.

The substrate 110 is a substrate which supports and protects various components of the display device 100. The substrate 110 may be formed of a glass or a plastic material having flexibility. When the substrate 110 is formed of a plastic material, for example, the substrate may be formed of polyimide (PI), but it is not limited thereto.

A buffer layer 111 is disposed on the substrate 110. The buffer layer 111 may reduce permeation of moisture or impurities through the substrate 110. Further, the buffer layer 111 may protect the transistor 120 from impurities such as alkali ions leaked from the substrate 110. Furthermore, the buffer layer 111 may enhance an adhesiveness between layers formed above the buffer layer and the substrate 110. The buffer layer 111 may be formed as a single layer of silicon nitride (SiNx) or silicon oxide (SiOx), or a multiple layer of silicon nitride (SiNx) or silicon oxide (SiOx), but is not limited thereto. The buffer layer 111 may be omitted based on a type and a material of the substrate 110, or a structure and a type of the transistor 120.

The transistor 120 is disposed on the buffer layer 111. The transistor 120 may be used as a driving element which drives the light emitting diode 140. The transistor 120 includes an active layer 121, a gate electrode 122, a source electrode 123, and a drain electrode 124. The transistor 120 illustrated in FIG. 2 is a driving transistor and is a top gate type thin film transistor in which the gate electrode 122 is disposed on the active layer 121. However, it is not limited thereto and the transistor 120 may be implemented as a bottom gate type transistor.

In FIG. 2, the driving transistor 120, among various transistors included in the display device 100, is illustrated, but the other transistors such as a switching transistor may also be disposed.

The active layer 121 is disposed on the buffer layer 111. The active layer 121 is an area in which a channel is formed when the transistor 120 is driven. The active layer 121 may be formed of an oxide semiconductor, amorphous silicon (a-Si), polycrystalline silicon (poly-Si), an organic semiconductor, or the like.

A gate insulating layer 112 is disposed on the active layer 121. The gate insulating layer 112 is a layer for electrically insulating the gate electrode 122 from the active layer 121 and may be formed of an insulating material. As illustrated in FIG. 3, the gate insulating layer 112 may be formed on the entire surface of the substrate 110, but is not limited thereto. That is, the gate insulating layer 112 may be patterned on the active layer 121 to have the same width as the gate electrode 122. The gate insulating layer 112 may be formed as a single layer of silicon nitride (SiNx) or silicon oxide (SiOx) which is an inorganic material, or a multiple layer of silicon nitride (SiNx) or silicon oxide (SiOx), but it is not limited thereto.

The gate electrode 122 is disposed on the gate insulating layer 112. The gate electrode 122 is disposed on the gate insulating layer 112 so as to overlap a channel region of the active layer 121. The gate electrode 122 may be any one of various metal materials, for example, molybdenum (Mo), aluminum (Al), chrome (Cr), gold (Au), titanium (Ti), nickel (Ni), neodymium (Nd), and copper (Cu), or an alloy of two or more of them, the gate electrode 122 may be one layer or multiple layers, but it is not limited thereto.

An interlayer insulating layer 113 is disposed on the gate electrode 122. The interlayer insulating layer 113 may be formed as a single layer of silicon nitride (SiNx) or silicon oxide (SiOx) which is an inorganic material, or a multiple layer of silicon nitride (SiNx) or silicon oxide (SiOx), but it is not limited thereto. In the interlayer insulating layer 113, contact holes through which the source electrode 123 and the drain electrode 124 are in contact with the source region and the drain region of the active layer 121, respectively, are formed.

The source electrode 123 and the drain electrode 124 are disposed on the interlayer insulating layer 113. The source electrode 123 and the drain electrode 124 are disposed on the same layer to be spaced apart from each other. The source electrode 123 and the drain electrode 124 are electrically connected to the active layer 121 through the contact holes of the interlayer insulating layer 113. The source electrode 123 and the drain electrode 124 may be any one of various metal materials such as molybdenum (Mo), aluminum (Al), chrome (Cr), gold (Au), titanium (Ti), nickel (Ni), neodymium (Nd), and copper (Cu), or an alloy of two or more of them, the source electrode 123 and the drain electrode 124 may be one layer or multiple layers, but it is not limited thereto.

A passivation layer 114 is disposed on the transistor 120. The passivation layer 114 may be disposed so as to cover the source electrode 123, the drain electrode 124, and the interlayer insulating layer 113. The passivation layer 114 may be formed as a single layer of silicon nitride (SiNx) or silicon oxide (SiOx), or a multiple layer of silicon nitride (SiNx) or silicon oxide (SiOx), but it is not limited thereto.

The color filter 130R is disposed on the passivation layer 114. The color filter 130R may be disposed to overlap the light emitting diode 140. Specifically, the color filter 130R may be disposed so as to correspond to the emission area EA. As described above, the display device 100 according to an embodiment of the present disclosure is a bottom emission type in which light emitted from the light emitting diode 140 is directed below the light emitting diode 140 and the substrate 110. Therefore, the color filter 130R may be disposed below the light emitting diode 140. Light emitted from the light emitting diode 140 passes through the color filter 130R and may be implemented as light having various colors. For example, the red sub pixel SPR emits red light so that the color filter 130R disposed in the red sub pixel SPR may be a red color filter.

A planarization layer 115 is disposed on the passivation layer 114. The planarization layer 115 is an insulating layer for protecting the transistor 120 and planarizing an upper portion of the transistor 120. A contact hole which exposes the drain electrode 124 of the transistor 120 is formed on the planarization layer 115. However, it is not limited thereto and a contact hole which exposes the source electrode 123 may also be formed on the planarization layer 115. The planarization layer 115 may be formed of one of acrylic resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The light emitting diode 140 is disposed on the planarization layer 115. The light emitting diode 140 includes a first electrode 141, a light emitting layer 142, and a second electrode 143.

The first electrode 141 is disposed on the planarization layer 115. The first electrode 141 is disposed so as to correspond to each of a plurality of sub pixels SP. The first electrode 141 may be an anode of the light emitting diode 140. The first electrode 141 may be electrically connected to a drain electrode 124 of the transistor 120. However, the first electrode 141 may be configured to be electrically connected to the source electrode 123 of the transistor 120 depending on a type of the transistor 120, a design manner of the driving circuit, and so forth. The first electrode 141 may be formed of a conductive material having a high work function to supply holes to the light emitting layer 142. For example, the first electrode 161 may be formed of a transparent conductive material such as indium tin oxide (ITO) and indium zinc oxide (IZO), but is not limited thereto.

The bank 116 is disposed on the planarization layer 115 and the first electrode 141. The bank 116 may be formed on the planarization layer 115 so as to cover an edge of the first electrode 141. The bank 116 is disposed at the boundary between the sub pixels SP which are adjacent to each other to reduce the mixture of light emitted from the light emitting diode 140 of each of a plurality of sub pixels SP. The bank 116 may include an opening OP overlapping the emission area EA. That is, in each of a plurality of sub pixels SP, an opening OP corresponding to the emission area EA may be formed. The opening OP may be configured to expose a part of the first electrode 141. The bank 116 may be an organic insulating material. For example, the bank 116 may be formed of one of acrylic resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The light emitting layer 142 is disposed on the first electrode 141 and the bank 116. The emission layer 142 may be formed as one layer over a plurality of sub pixels SP. That is, the emission layers 142 of each of a plurality of sub pixels SP are connected to each other to be integrally formed. The emission layer 142 may be configured as one emission layer or may have a structure in which a plurality of emission layers which emits different color light is laminated. The light emitting layer 142 may be configured by a white light emitting layer. The light emitting layer 142 may further include an organic layer such as a hole injection layer, a hole transport layer, an electron transport layer, and an electron injection layer.

In the meantime, in the present disclosure, even though it is described that the light emitting layer 142 is a white light emitting layer, the light emitting layer 142 may be an organic layer which emits light having a specific color. For example, the light emitting layer 142 may be configured by a red light emitting layer, a green light emitting layer, and a blue light emitting layer. And in this case, the color filter may be omitted.

The second electrode 143 is disposed on the light emitting layer 142. The second electrode 143 may be formed as one layer over the entire surface of the substrate 110. That is, the second electrodes 143 of each of a plurality of sub pixels SP are connected each other to be integrally formed. The second electrode 143 supplies electrons to the light emitting layer 142 so that the second electrode may be formed of a conductive material having a low work function. For example, the second electrode 143 may be formed of a transparent conductive material such as indium tin oxide (ITO) or indium zinc oxide (IZO), a metal alloy such as MgAg, or a ytterbium (Yb) alloy, and may further include a metal doping layer, but is not limited thereto.

In the meantime, even though it is not illustrated in FIG. 3, an encapsulation unit or structure may be disposed on the light emitting diode 140. The encapsulation unit may protect the light emitting diode 140 from moisture and oxygen permeating into the display device 100 from the outside. The encapsulating unit may have a structure in which an inorganic layer and an organic layer are alternately laminated.

Even though in FIG. 3, only the structure of the red sub pixel SPR is illustrated, the white sub pixel SPW, the blue sub pixel SPB, and the green sub pixel SPG may have the same structure. However, in the case of the white sub pixel SPW, the color filter may be omitted. Further, the color filters disposed in the blue sub pixel SPB and the green sub pixel SPG may be a blue color filter and a green color filter, respectively.

FIG. 4A is a cross-sectional view taken along the line IVa-IVa′ of FIG. 2. FIG. 4B is a cross-sectional view taken along the line IVb-IVb′ of FIG. 2. FIG. 4C is a cross-sectional view taken along the line IVc-IVc′ of FIG. 2. FIG. 4D is a cross-sectional view taken along the line IVd-IVd′ of FIG. 2.

Referring to FIGS. 4A to 4D, in the opening OP of each of a plurality of sub pixels SP, at least one partition 117 is disposed. Further, color filters 130R, 130B, and 130G are disposed in the red sub pixel SPR, the blue sub pixel SPB, and the green sub pixel SPG, respectively. Here, a color filter 130R disposed in the red sub pixel SPR is a red color filter, a color filter 130B disposed in the blue sub pixel SPB is a blue color filter, and a color filter 130G disposed in the green sub pixel SPG is a green color filter.

The partition 117 is disposed on the first electrode 141 in the opening OP. The light emitting layer 142 and the second electrode 143 may be disposed on the first electrode 141, the bank 116, and the partition 117. The partition 117 may be formed of the same material as the bank 116. That is, the partition 117 may be formed of one of acrylic resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

A cross section of the partition 117 may have an inverted trapezoidal shape. That is, a width of an upper surface of the partition 117 may be larger than a width of a lower surface of the partition 117. Here, the upper surface of the partition 117 refers to an area spaced apart from the first electrode 141 and the lower surface of the partition 117 may refer to an area which is in contact with the first electrode 141. Since the partition 117 has an inverted trapezoidal shape, the light emitting layer 142 and the second electrode 143 may have a structure which is not continuous, but is disconnected, due to the partition 117. That is, when the light emitting layer 142 and the second electrode 143 are deposited, it may be difficult for the light emitting layer 142 and the second electrode 143 to be deposited on a portion blocked by the upper portion of the partition 117. Accordingly, the light emitting layer 142 disposed at one side of the partition 117 may be disposed to be discontinuous from the light emitting layer 142 disposed at the other side of the partition 117. Further, the second electrode 143 disposed at one side of the partition 117 may be disposed to be discontinuous from the second electrode 143 disposed at the other side of the partition 117.

The light emitting layer 142 and the second electrode 143 are disconnected by the partition 117 so that the inside of the opening OP may be divided into a plurality of emission areas EA. That is, in the emission area EA, the first electrode 141 and the light emitting layer 142 are in direct contact to each other to emit light. Further, in the area corresponding to the partition 117, the first electrode 141 and the light emitting layer 142 may overlap while being spaced apart from each other. Therefore, in the area corresponding to the partition 117, light may not be emitted.

Light emitted from a light emitting layer of the display device passes through various components of the display device to be released to the outside of the display device. However, there may be light which does not come out of the display device but is trapped in the display device, among light emitted from the light emitting layer. For example, there may be light trapped therein by the total reflection at the interface of components of the display device, which may be represented as waveguide mode loss. Specifically, the waveguide mode loss may be strongly generated in the hole transport layer or the electron transport layer of the light emitting layer. The light extraction efficiency of the display device is lowered and the luminance of the display device may be reduced, due to the waveguide mode loss.

In the meantime, the waveguide mode loss may be approximated by the following Equation 1.

N(k)˜Ak²/4π±Lk/4π Equation 1

Here, N is a number of waveguide modes, k is a wavenumber, A is an area of the emission area, and L is a length of the emission area. That is, referring to Equation 1, the larger the area of the emission area and the wavenumber, the larger the waveguide mode loss.

The display device 100 according to an embodiment of the present disclosure may include a plurality of emission areas EA in one sub pixel SP to improve the waveguide mode loss. That is, the opening OP of the sub pixel SP is divided into a plurality of emission areas EA to reduce an area of one emission area EA. In other words, one sub pixel SP may include a plurality of emission areas EA having a relatively small area. Accordingly, the waveguide mode loss is improved and the light extraction efficiency may be improved. It should be understood that “divided into” includes the meaning that one group or element contains different items or objects. The term “divided into” does not require the action of dividing. The term divided into means it is possible, by inclusion of the partition 117, to physically isolate the plurality of emission areas EA from each other.

The opening OP of the sub pixel SP may be divided into a plurality of emission areas EA by means of the partition 117. Specifically, before depositing the light emitting layer 142, the partition 117 may be disposed on the first electrode 141 in the opening OP. At this time, a cross section of the partition 117 may have an inverted trapezoidal shape. Therefore, the light emitting layer 142 is disposed to be discontinuous by the partition to be divided in the opening OP. Further, the emission area EA may be an area in which the first electrode 141 and the light emitting layer 142 are in direct contact. That is, the light emitting layer 142 is divided in the opening OP so that an area of the light emitting layer 142 of one emission area EA may be reduced. Specifically, since the waveguide mode loss mostly occurs in the light emitting layer 142, the waveguide mode loss may be more effectively reduced by dividing the light emitting layer 142.

The cross-section of the partition 117 has an inverted trapezoidal shape so that the light reflected by the partition 117 may be directed to the emission area EA again. Accordingly, an amount of amplified light may be increased by a micro cavity structure. Here, according to the micro cavity structure, light is repeatedly reflected between the first electrode 141 and the second electrode 143 which are spaced apart from each other with an optical length therebetween so that light of a specific wavelength is amplified by the constructive interference. If the cross-section of the partition 117 has a trapezoidal shape, light reflected by the partition 117 may be emitted to the outside as it is. In this case, light extracted by the micro cavity effect and light unextracted by the micro cavity effect are mixed to change a color coordinate and to deteriorate a color viewing angle. Accordingly, the partition 117 having an inverted trapezoidal cross section may increase an amount of extracted light and improve the color viewing angle by the micro cavity effect.

Referring to FIGS. 2 and 4A to 4D, the red sub pixel SPR, the white sub pixel SPW, the blue sub pixel SPB, and the green sub pixel SPG may be formed to have the same shape. Further, the openings OP of the red sub pixel SPR, the white sub pixel SPW, the blue sub pixel SPB, and the green sub pixel SPG may be formed with the same area. However, the efficiency of each sub pixel SP may be different.

For example, the red sub pixel SPR may include four emission areas EA including three partitions 117 which are spaced apart from each other. The white sub pixel SPW may include five emission areas EA including four partitions 117 which are spaced apart from each other. The blue sub pixel SPB may include three emission areas EA including two partitions 117 which are spaced apart from each other. The green sub pixel SPG may include two emission areas EA including one partition 117. At this time, the smaller the area of the emission area EA, the smaller the waveguide mode loss so that the light extraction efficiency may be improved. The red sub pixel SPR, the white sub pixel SPW, the blue sub pixel SPB, and the green sub pixel SPG may divide the opening OP having the same area into four, five, three, and two areas to configure the emission area EA, respectively. Accordingly, the area of the emission area may be reduced in the order of the green sub pixel SPG, the blue sub pixel SPB, the red sub pixel SPR, and the white sub pixel SPW. Accordingly, the luminous efficiency may be configured to be higher in the order of the white sub pixel SPW, the red sub pixel SPR, the blue sub pixel SPB, and the green sub pixel SPG.

In a general display device, the opening by a bank of the sub pixel may correspond to one emission area. Further, in order to make the luminous efficiency of the sub pixel which emits different light according to a specification of the display device different, the emission area is configured to have a different area. For example, in order to make the efficiency of the white sub pixel highest, the emission area of the white sub pixel is configured to have the largest area. Further, in order to make the efficiency of the green sub pixel lowest, the emission area of the green sub pixel is configured to have the smallest area. In this case, the shapes of each of the sub pixels are not uniform so that there is a problem in that the image of the display device is not uniform.

Accordingly, in the display device 100 according to an embodiment of the present disclosure, the efficiencies of a plurality of sub pixels SP may be adjusted to be different from each other while forming a plurality of sub pixels SP to have the same shape and the same area. For example, as illustrated in FIGS. 2 and 4A to 4D, the openings OP of the red sub pixel SPR, the white sub pixel SPW, the blue sub pixel SPB, and the green sub pixel SPG have the same shape and the same area, but the divided emission areas EA may have different areas. Accordingly, the image of the display device 100 may be uniformly output and the display quality may be improved.

In the meantime, even though it is illustrated in the drawings that the areas of the divided emission areas EA are increased in the order of the white sub pixel SPW, the red sub pixel SPR, the blue sub pixel SPB, and the green sub pixel SPG, the present disclosure is not limited thereto. That is, the number of divided openings OP of each sub pixel SP may vary depending on the design of the display device. Further, even though it is illustrated in the drawings that the numbers of emission areas EA included in each of the red sub pixel SPR, the white sub pixel SPW, the blue sub pixel SPB, and the green sub pixel SPG are different from each other, the present disclosure is not limited thereto. That is, the numbers of emission areas EA included in some of the red sub pixel SPR, the white sub pixel SPW, the blue sub pixel SPB, and the green sub pixel SPG may be the same. Further, only some of the red sub pixel SPR, the white sub pixel SPW, the blue sub pixel SPB, and the green sub pixel SPG may include the partition 117. That is, some of the red sub pixel SPR, the white sub pixel SPW, the blue sub pixel SPB, and the green sub pixel SPG do not include the partition 117 to include only one emission area EA.

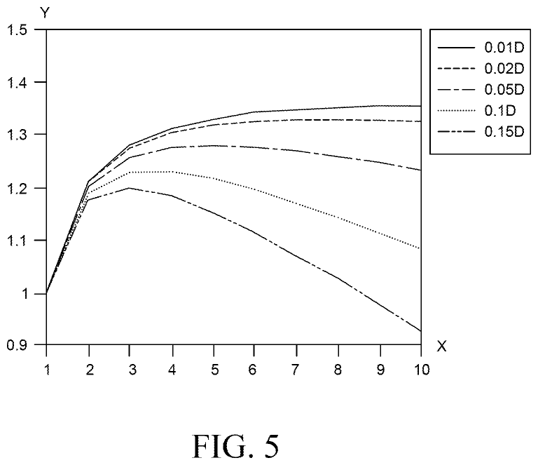

FIG. 5 is a graph illustrating a change in a light efficiency according to a number of emission areas. In FIG. 5, an X axis (horizontal axis) is the number of emission areas EA disposed in one sub pixel SP and a Y axis (vertical axis) is a rate of change of light efficiency. The rate of change of light efficiency is calculated by “(emission area)X(1-waveguide mode loss rate)/(reference emission area)X(1-reference waveguide mode loss rate)”. Here, the reference emission area and the reference waveguide mode loss rate refer to an area of the emission area EA and the waveguide mode loss rate when the partition 117 is not disposed in the opening OP. Further, the emission area and the waveguide mode loss rate refer to a sum of areas of a plurality of emission areas EA and the waveguide mode loss rate when the partition 117 is disposed in the opening OP. Further, each of 0.01D, 0.02D, 0.05D, 0.1D, and 0.15D may refer to widths of the partitions 117. Here, the width of the partition 117 may be a width of the largest cross-section of the partition 117. Further, D may be a length of the shortest side of the opening OP. In each case, the size and the area of the opening of the sub pixel are set to be equal.

Referring to FIG. 5, it is confirmed that when the width of the partition 117 is 0.01D or 0.02D, the larger the number of divided emission areas EA, the higher the luminous efficiency. In other words, when the width of the partition 117 is 0.01D or 0.02D, as the area of the divided emission area EA is reduced, the luminous efficiency is improved. When there is a partition 117 in the opening OP, an overall aperture rate of the opening OP may be slightly reduced. However, the opening OP is divided into a plurality of emission areas EA having a small area so that the waveguide mode loss is reduced to improve light extraction efficiency. That is, the improvement of the light extraction efficiency obtained by dividing the emission area EA may be significant more than the lowering of the luminous efficiency according to the reduction of the aperture ratio. Therefore, when the width of the partition 117 is small, the larger the number of divided emission areas EA, the better the luminous efficiency.

When the width of the partition 117 is 0.05D, 0.1D, or 0.15D, it is confirmed that as the number of emission areas EA is increased, the luminous efficiency is improved and then gradually reduced. Specifically, when the width of the partition 117 is 0.15D, it is confirmed that if the number of emission areas EA is 10, the efficiency is slightly lowered than one emission area. Specifically, as the number of divided emission areas EA is increased, the entire area of the partition 117 is increased so that the entire aperture ratio of the opening OP is reduced. Specifically, when the width of the partition 117 is large, the lowering of the luminous efficiency due to the reduction of the aperture ratio may significantly affect.

The width of the partition 117 may be 0.01 to 0.15 times a length of a shortest side of the opening. If the width of the partition 117 is smaller than 0.01 times the length of the shortest side of the opening, the light emitting layer 142 may not be easily disconnected. If the width of the partition 117 is larger than 0.15 times the length of the shortest side of the opening, the aperture ratio is reduced to deteriorate the luminous efficiency.

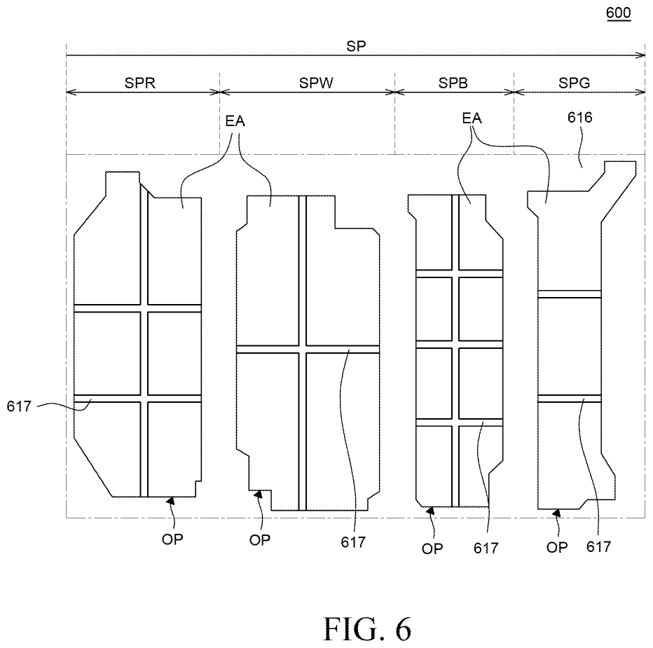

FIG. 6 is a plan view of a display device according to another embodiment of the present disclosure. The display device 600 of FIG. 6 is substantially the same as the display device 100 of FIGS. 1 to 4D except for the shapes of the sub pixel SP, a bank 616, and a partition 617 so that a redundant description will be omitted. In FIG. 6, for the convenience of description, among various configurations of the display device 600, a bank 616 and a partition 617 are illustrated, and other elements may be omitted from view.

Referring to FIG. 6, the sub pixel SP of the display device 600 may include a red sub pixel SPR, a white sub pixel SPW, a blue sub pixel SPB, and a green sub pixel SPG. Here, the red sub pixel SPR, the white sub pixel SPW, the blue sub pixel SPB, and the green sub pixel SPG may have different areas. Further, the openings OP of each of the red sub pixel SPR, the white sub pixel SPW, the blue sub pixel SPB, and the green sub pixel SPG may have different areas and shapes.

The openings OP of each of the red sub pixel SPR, the white sub pixel SPW, the blue sub pixel SPB, and the green sub pixel SPG may be divided into a plurality of emission areas EA. The numbers of emission areas EA of each of the red sub pixel SPR, the white sub pixel SPW, the blue sub pixel SPB, and the green sub pixel SPG may be different from each other.

Specifically, the opening OP of the red sub pixel SPR may be divided into six emission areas EA. At this time, the partition 617 disposed in the red sub pixel SPR may be formed such that two lines extending in a first direction and one line extending in a second direction intersect. Further, all six emission areas EA of the red sub pixel SPR may have different shapes and areas.

The opening OP of the white sub pixel SPW may be divided into four emission areas EA. At this time, the partition 617 disposed in the white sub pixel SPW may be formed such that one line extending in a first direction and one line extending in a second direction intersect. Further, all four emission areas EA of the white sub pixel SPW may have different shapes and areas.

The opening OP of the blue sub pixel SPB may be divided into eight emission areas EA. At this time, the partition 617 disposed in the blue sub pixel SPB may be formed such that three lines extending in the first direction and one line extending in the second direction intersect. Further, all eight emission areas EA of the blue sub pixel SPB may have different shapes and areas.

The opening OP of the green sub pixel SPG may be divided into three emission areas EA. At this time, the partition 617 disposed in the green sub pixel SPG may be formed such that two lines extending in the first direction are spaced apart from each other. Further, all three emission areas EA of the green sub pixel SPG may have different shapes and areas.

In the meantime, the structure of a plurality of sub pixels SP illustrated in FIG. 6 is for the convenience of description so that the present disclosure is not limited thereto. That is, the structure of a plurality of sub pixels SP may be configured to be different from FIG. 6 according to the design of the display device. Further, even though it is illustrated in the drawings that the numbers of emission areas EA included in each of the red sub pixel SPR, the white sub pixel SPW, the blue sub pixel SPB, and the green sub pixel SPG are different from each other, the present disclosure is not limited thereto. That is, the numbers of emission areas EA included in some of the red sub pixel SPR, the white sub pixel SPW, the blue sub pixel SPB, and the green sub pixel SPG may be the same. Further, only some of the red sub pixel SPR, the white sub pixel SPW, the blue sub pixel

SPB, and the green sub pixel SPG may include the partition 617. That is, some of the red sub pixel SPR, the white sub pixel SPW, the blue sub pixel SPB, and the green sub pixel SPG do not include the partition 617 to include only one emission area EA.

In the display device 600 according to another embodiment of the present disclosure, the opening OP is divided into a plurality of emission areas EA to reduce an area of one emission area EA. Accordingly, the loss due to the waveguide mode is reduced and the light extraction efficiency is improved.

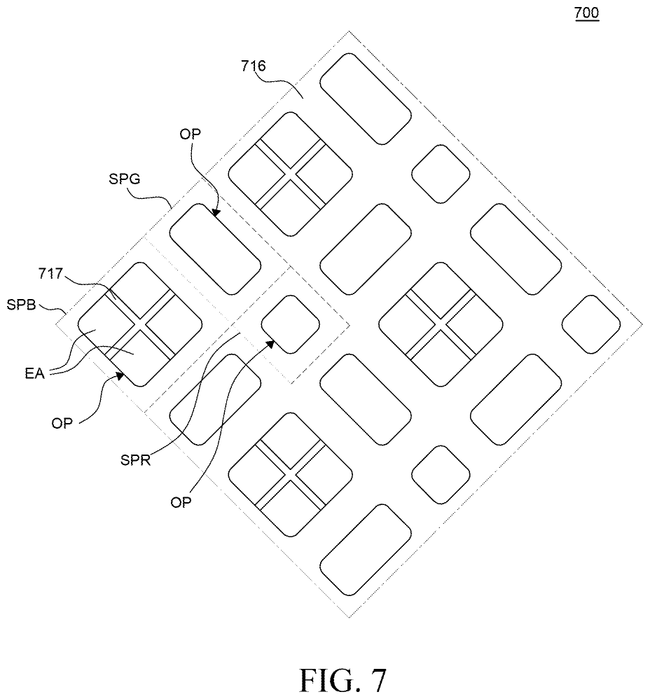

FIG. 7 is a plan view of a display device according to still another embodiment of the present disclosure. In FIG. 7, for the convenience of description, among various configurations of the display device 700, a bank 716 and a partition 717 are illustrated, and other elements may be omitted from view.

Referring to FIG. 7, the sub pixel SP of the display device 700 may include a red sub pixel SPR, a green sub pixel SPG, and a blue sub pixel SPB. At this time, a red light emitting diode including a red light emitting layer is disposed in the red sub pixel SPR, a green light emitting diode including a green light emitting layer is disposed in the green sub pixel SPG, and a blue light emitting diode including a blue light emitting layer is disposed in the blue sub pixel SPB. That is, the light emitting layer of each sub pixel SP is an organic layer which emits different color light so that a separate color filter may be omitted from the display device 700. Further, the light emitting layer may be patterned so as to correspond to each sub pixel SP.

The red sub pixel SPR, the green sub pixel SPG, and the blue sub pixel SPB may have different areas from each other. Further, the openings OP of each of the red sub pixel SPR, the green sub pixel SPG, and the blue sub pixel SPB may have different areas from each other. At this time, the opening OP of the blue sub pixel SPB may be divided into four emission areas EA. The openings OP of the red sub pixel SPR and the green sub pixel SPG are not divided, but may include only one emission area EA.

Generally, blue light among red light, green light, and blue light has the lowest wavelength. Referring to Equation 1, the larger the wavenumber, the more the waveguide mode loss. At this time, the wavenumber k is a reciprocal number of the wavelength. Therefore, the smaller the wavelength, the more the waveguide mode loss. Accordingly, the waveguide mode loss is the largest in the blue sub pixel SPB, among the red sub pixel SPR, the green sub pixel SPG, and the blue sub pixel SPB. Therefore, as illustrated in FIG. 7, the opening OP of the blue sub pixel SPB is divided into a plurality of emission areas EA having a small area so that the waveguide mode loss in the blue sub pixel SPB may be improved. Further, the current which is input to the blue sub pixel SPB is reduced so that the efficiency and the lifespan of the blue light emitting diode may be improved.

In the meantime, the structure of a plurality of sub pixels SP illustrated in FIG. 7 is for the convenience of description so that the present disclosure is not limited thereto. That is, the structure of a plurality of sub pixels SP may be configured to be different from FIG. 7 according to the design of the display device. Further, even though in the drawings, the blue sub pixel SPB includes four emission areas EA and the red sub pixel SPR and the green sub pixel SPG include one emission area, the present disclosure is not limited thereto. That is, the numbers of emission areas EA of each of the red sub pixel SPR, the blue sub pixel SPB, and the green sub pixel SPG may be different.

In the display device 700 according to still another embodiment of the present disclosure, the opening OP is divided into a plurality of emission areas to improve the waveguide mode loss. Specifically, only the opening OP of some sub pixels SP in which the waveguide mode loss is relatively significant, among a plurality of sub pixels SP, may be divided into a plurality of emission areas EA. Accordingly, the efficiency in each of a plurality of sub pixels SP is uniformly maintained to improve the lifespan and the quality of the display device 700.

The embodiments of the present disclosure can also be described as follows:

According to an aspect of the present disclosure, a display device includes a substrate including a plurality of sub pixels; a first electrode on the substrate and corresponding to each of the plurality of sub pixels; a bank on the first electrode and including an opening which exposes the first electrode; a partition on the first electrode in the opening; a light emitting layer on the first electrode and the partition; and a second electrode on the light emitting layer, in which the light emitting layer is disposed to have a structure disconnected by the partition in the opening.

The second electrode may be disposed to have a structure disconnected by the partition in the opening.

The light emitting layer and the second electrode disposed at one side of the partition may be discontinuously disposed from the light emitting layer and the second electrode disposed at the other side of the partition.

Each of the plurality of sub pixels may include at least one of an emission area in which the first electrode and the light emitting layer are in direct contact with each other, some of the plurality of sub pixels may include a plurality of emission areas and the partition may be disposed to divide the opening into the plurality of emission areas.

The first electrode and the light emitting layer overlapping in an area corresponding to the partition may be spaced apart from each other.

The plurality of sub pixels may include a red sub pixel, a green sub pixel, a blue sub pixel, and a white sub pixel, and the partition may be disposed in at least one of the red sub pixel, the green sub pixel, the blue sub pixel, and the white sub pixel.

The numbers of emission areas included in each of the red sub pixel, the green sub pixel, the blue sub pixel, and the white sub pixel may be different from each other.

The numbers of emission areas included in some of the red sub pixel, the green sub pixel, the blue sub pixel, and the white sub pixel may be the same.

The plurality of sub pixels may include a red sub pixel, a green sub pixel, and a blue sub pixel, and the partition may be disposed in at least one of the red sub pixel, the green sub pixel, and the blue sub pixel.

The numbers of emission areas included in each of the red sub pixel, the green sub pixel, and the blue sub pixel may be different from each other.

The numbers of emission areas included in some of the red sub pixel, the green sub pixel, and the blue sub pixel may be the same.

A cross-section of the partition may have an inverted trapezoidal shape.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a plurality of sub pixels;
a first electrode on the substrate and corresponding to each of the plurality of sub pixels;
a bank on the first electrode and including an opening which exposes the first electrode;
a partition on the first electrode in the opening;
a light emitting layer on the first electrode and on the partition, the light emitting layer being electrically disconnected from the first electrode at the location of the partition; and
a second electrode on the light emitting layer.

2. The display device according to claim 1, wherein the second electrode is electrically disconnected from the first electrode by the partition in the opening.

3. The display device according to claim 1, wherein the light emitting layer and the second electrode disposed at one side of the partition have are spaced from the light emitting layer and the second electrode disposed at the other side of the partition.

4. The display device according to claim 1, wherein each of the plurality of sub pixels includes at least one of an emission area in which the first electrode and the light emitting layer are in direct contact with each other,
wherein some of the plurality of sub pixels include a plurality of emission areas, and
wherein the plurality of emission areas of one of the plurality of sub pixels are separated from each other in the opening by the partition.

5. The display device according to claim 4, wherein the first electrode and the light emitting layer overlapping in an area corresponding to the partition are spaced apart from each other.

6. The display device according to claim 4, wherein the plurality of sub pixels includes a red sub pixel, a green sub pixel, a blue sub pixel, and a white sub pixel, and
wherein the partition is disposed in at least one of the red sub pixel, the green sub pixel, the blue sub pixel, and the white sub pixel.

7. The display device according to claim 6, wherein the numbers of emission areas included in each of the red sub pixel, the green sub pixel, the blue sub pixel, and the white sub pixel are different from each other.

8. The display device according to claim 6, wherein the numbers of emission areas included in some of the red sub pixel, the green sub pixel, the blue sub pixel, and the white sub pixel are the same.

9. The display device according to claim 4, wherein the plurality of sub pixels includes a red sub pixel, a green sub pixel, and a blue sub pixel, and
wherein the partition is disposed in at least one of the red sub pixel, the green sub pixel, and the blue sub pixel.

10. The display device according to claim 9, wherein the numbers of emission areas included in each of the red sub pixel, the green sub pixel, and the blue sub pixel are different from each other.

11. The display device according to claim 9, wherein the numbers of emission areas included in some of the red sub pixel, the green sub pixel, and the blue sub pixel are the same.

12. The display device according to claim 1, wherein a cross-section of the partition has an inverted trapezoidal shape.

13. The display device according to claim 4, wherein, in one of the plurality of sub pixels, the emission areas have different shapes and areas.
